(19) United States
(12) Patent Application Publication
(10) Pub. No.: US 2026/0290769 A1
(43) Pub. Date: Sep. 24, 2026

(54) WAFER PROCESSING METHOD AND INTEGRATED ETCHING-DEPOSITION EQUIPMENT FOR WAFER PROCESSING

(71) Applicant: Advanced Micro-Fabrication Equipment Inc. China, Shanghai (CN)

(72) Inventors: Xingjian CHEN, Shanghai (CN); Huanglin CHEN, Shanghai (CN); Shenjian LIU, Shanghai (CN)

(21) Appl. No.: 19/137,534

(22) PCT Filed: Nov. 29, 2023
(86) PCT No.: PCT/CN2023/135062

§ 371 Date: Jun. 12, 2026

(30) Foreign Application Priority Data
Dec. 12, 2022 (CN) 202211598096.7

(51) Int. Cl. H01J 37/32; H10P 72/00; H10P 74/00

(52) U.S. Cl. CPC H01J 37/3299; H01J 37/32743; H10P 72/0421; H10P 74/238; H01J 2237/332; H01J 2237/334

(57) ABSTRACT

Disclosed are a wafer processing method and integrated etching-deposition equipment for wafer processing. The method includes: providing a plasma processing apparatus; providing a to-be-processed wafer and placing the to-be-processed wafer in a plasma processing chamber; activating a plasma radio frequency source, introducing an etching gas to etch an etching region, so as to form a hole or a trench; and performing monitoring, switching between introducing a first mask precursor to deposit a mask or introducing the etching gas to continue etching according to a monitoring situation till monitoring that the hole or the trench formed in the etching region meets a target etching requirement, where the first mask precursor includes substituted methylsilane. Through real-time monitoring, a wafer processing working mode may be switched to an etching mode or a mask deposition mode for in-situ etching of the to-be-processed wafer or in-situ mask deposition without taking the to-be-processed wafer from the plasma processing chamber, so that the cost is lowered and the production cycle is shortened. The method is suitable for etching a large-sized silicon hole and a microstructure with a high or ultrahigh aspect ratio.

### TECHNICAL FIELD

The present disclosure relates to the technical field of semiconductors, and in particular, to a wafer processing method and integrated etching-deposition equipment for wafer processing.

### BACKGROUND

In the process of manufacturing an integrated circuit chip, it is required to design a mask as a barrier layer in a process of manufacturing a microstructure to control the dimension of the microstructure. Common mask materials include a photoresist (PR), a hard material amorphous carbon (C), boron (B), and the like. These mask materials have their own excellence but have their own limitations.

In some processes, the PR is cured as a mask. However, due to material performance and manufacturing process of the PR, in an oxygen radical environment, the etching rate is higher, which is prone to result in a large critical dimension (CD), so that it is not suitable to serve as a mask of a microstructure with a high aspect ratio or depth-to-width ratio, for example, a microstructure with the aspect ratio greater than 5:1.

A carbon (C) mask is generated by plasma-enhanced physical vapor deposition (PEPVD). Compared with the PR mask, due to the PEPVD deposition process, the carbon (C) mask has a good etching-resistant blocking effect. For example, in a process where O₂/CO/S is taken as a process gas, the carbon (C) mask can be selectively etched at an etching rate of 10 nm/s, and the etching rate of holes is to be at least increased by 1-2 orders of magnitudes. The carbon (C) mask shows the etching-resistant blocking effect, and can be used for forming a relatively deep straight hole as a mask. However, in a later continuous etching process, due to the accumulation of polymers on hole walls, the holes may be blocked, so that the etching rate is decreased, and the holes etched in the later period have defects in shape and CD, resulting in deformed holes or curved holes, or the like.

As can be seen, existing masks are not suitable for a wafer processing process for a microstructure with a high aspect ratio or depth-to-width ratio.

Moreover, in a conventional wafer processing process, in particular, the microstructure with a high or ultrahigh aspect ratio, along with etching, the mask will be etched gradually and is not enough to shield, and it is required to stop etching. The wafer has to be taken out of the etching chamber, and a new mask has to be fabricated.

### SUMMARY

An objective of the present disclosure is to provide a more etching-resistant SiC mask to replace an amorphous C layer. The mask can be formed in a wafer processing process, and a new SiC mask is formed in situ according to an etching situation. In-situ etching obtains a microstructure with a high or ultrahigh aspect ratio without taking out the wafer many times to manufacture the mask again.

In order to achieve the above objective, the present disclosure provides a wafer processing method, including:
providing a plasma processing apparatus, comprising a plasma processing chamber for providing a plasma environment;
providing a to-be-processed wafer, having a mask region and an etching region; placing the to-be-processed wafer in the plasma processing chamber;
introducing an etching gas into the plasma processing chamber, and activating a plasma radio frequency source, the etching gas being dissociated into an etching gas plasma and the etching gas plasma etching the etching region to form a hole or a trench; and
monitoring the to-be-processed wafer, and according to a monitoring situation, switching between introducing a first mask precursor to deposit a mask or introducing the etching gas to continue etching till monitoring that the hole or the trench formed in the etching region meets a target etching requirement, where the first mask precursor includes substituted methylsilane, and an atomic ratio of silicon to carbon is 1:1; the first mask precursor is dissociated into a first mask precursor plasma in the plasma processing chamber, and the first mask precursor plasma deposits a first mask layer in the mask region.

Optionally, a method for depositing the first mask layer is at least one of PECVD or PEALD.

Optionally, a process temperature in the plasma processing chamber is 50° C.-300° C.

Optionally, in the substituted methylsilane, H atoms are partially or totally substituted with F and/or Cl.

Optionally, the substituted methylsilane is at least one of CH₃SiCl₃, CH₂ClSiHCl₂, CHCl₂SiH₂Cl, CH₃SiF₃, CH₂FSiHCl₂, and CHF₂SiH₂F.

Optionally, the first mask layer includes a SiC mask.

Optionally, the first mask precursor further includes an oxygen-containing gas.

Optionally, the oxygen-containing gas includes at least one of oxygen, ozone or hydrogen peroxide.

Optionally, the first mask layer includes a SiC film and/or a SiOC film.

Optionally, a monitoring mode for monitoring the to-be-processed wafer is real-time monitoring.

Optionally, a thickness of the first mask layer is 1 A−n×10² nm, n=1-10.

Optionally, the mask region of the to-be-processed wafer further includes a second mask layer.

Optionally, the second mask layer includes a photoresist.

Optionally, the second mask layer further includes an amorphous carbon (C) layer or a boron (B) layer, located under the photoresist.

Optionally, an aspect ratio of the hole or the trench is 5:1-500:1.

Optionally, the aspect ratio of the hole or the trench is 40:1-200:1.

The present disclosure further provides integrated etching-deposition equipment for the wafer processing method, including:
a plasma processing apparatus for wafer etching processing, provided with a plasma processing chamber;
an online monitoring system, connected to the plasma processing apparatus for monitoring states of a mask region and an etching region of a to-be-processed wafer in the plasma processing chamber in real time in a water processing process; and
a gas inlet system, including an etching gas inlet pipeline and a first mask precursor gas inlet pipeline, connected with the plasma processing chamber respectively for introducing an etching gas or a first mask precursor into the plasma processing chamber.

Optionally, the online monitoring system includes an energy dispersive X-ray spectrometer (EDX) for monitoring the thickness of a first mask layer or a second mask layer in the mask region.

Optionally, the online monitoring system includes an OES monitoring system for online monitoring an etching state of the etching region.

Optionally, the first mask precursor gas inlet pipeline is further provided with a millisecond-level mass flow controller for metering a flow of the first mask precursor.

Optionally, the plasma processing apparatus includes an inductively coupled plasma (ICP) reaction apparatus or a capacitively coupled plasma (CCP) reaction apparatus.

Compared with the prior art, the technical solution of the present disclosure at least has the following beneficial effects:
1) By the wafer processing method provided by the present disclosure, the SiC mask with more excellent plasma etching-resistant performance is formed in situ in the plasma processing chamber, which is used for etching the microstructure with a high aspect ratio in wafer processing.
2) According to the present disclosure, real-time monitoring is performed in the wafer processing process, and an etching mode or a mask deposition mode can be switched to perform in-situ etching or in-situ mask deposition on the to-be-processed wafer till the etched hole or trench reaches the target etching requirement. In the wafer processing process, it is not required to take out the wafer from the plasma processing chamber to manufacture the mask, so that the production cycle is shortened and the cost is lowered. The method is suitable for etching a large-sized silicon hole and a microstructure with a high or ultrahigh aspect ratio.

### BRIEF DESCRIPTION OF THE DRAWINGS

FIG. 1 is a flowchart of a wafer processing method provided by the present disclosure.

FIG. 2 is a schematic structural diagram of integrated etching-deposition equipment for wafer processing provided by the present disclosure.

FIG. 3 is an SEM image of a first mask layer SiC deposited in the Embodiment 1 of the present disclosure.

FIG. 4 is an elemental spectrogram in a plasma processing chamber in a process of depositing the first mask in the Embodiment 1 of the present disclosure.

FIG. 5 is an EDX scanned image of the first mask layer SiC deposited in the Embodiment 1 of the present disclosure.

FIG. 6 is an SEM image of a first mask layer SiOC deposited in the Embodiment 2 of the present disclosure.

### REFERENCE NUMERALS

1, to-be-processed wafer;
10, plasma processing apparatus;
11, plasma processing chamber;
20, online monitoring system;
30, gas inlet system.

### DETAILED DESCRIPTION OF THE EMBODIMENTS

The technical solutions for the present disclosure will be described clearly and intactly below in conjunction with the drawings. Apparently, the described embodiments are merely a part of embodiments, rather than all the embodiments, of the present disclosure. Based on the embodiments of the present disclosure, all other embodiments obtained by those of ordinary skill in the art without creative work are included in the protection scope of the present disclosure.

In the descriptions of the present disclosure, it should be noted that an orientation relationship or a position relationship indicated by the terms “upper”, “lower”, “left”, “right”, “perpendicular”, “horizontal”, “inside”, “outside”, and the like is an orientation relationship or a position relationship based on the drawing and is merely for ease of describing present disclosure and simplifying the description, rather than indicating or implying that a specified apparatus or element necessarily has a specific orientation or is constructed and operated in a specific orientation. Therefore, the terms should not be construed as a limitation on the present disclosure. In addition, the terms “first”, “second”, “third”, and the like are just used for the purpose of description, but cannot be understood as indicating or implying the relative importance thereof.

In the description of the present disclosure, unless otherwise specified, the terms “mount”, “connect”, “connection”, and the like should be understood in a broad sense, for example, it may be a fixed connection or a detachable connection or an integrated connection; it may be a mechanical connection; it may be a direct connection or an indirect connection via an intermediate, or it may be an internal connection of two components. Those of ordinary skill in the art can understand the specific meanings of the above terms in the present disclosure in specific situations.

In order to form microstructures such as holes or trenches in the wafer, a mask region and an etching region are usually disposed of the to-be-processed wafer. The etching region is used for forming the microstructures such as holes or trenches, and the mask region is used for forming a mask for shield protection on the wafer in the mask region in the plasma environment, so as to prevent the to-be-processed wafer from being damaged.

For etching the microstructure with the high or ultrahigh aspect ratio, the required etching characteristics include: high etching selectivity on the mask (for example, the amorphous carbon mask), low side wall etching with a straight contour, a high etching rate, and the like. In the process of forming the wafer with the structure with the high or ultrahigh aspect ratio, due to various problems of plasma etching resistance, etching selectivity, insufficient thickness of the mask and the like of the conventional mask, in the etching process, it is required to take out the to-be-processed wafer from the plasma processing chamber many times to manufacture the mask again, resulting in prolongment of the production cycle and increase of the cost. For example, conventionally, the PR serves as the mask. In order to form the microstructure with the high or ultrahigh aspect ratio, the PR is required to be thicker. However, the thicker the PR is, the longer the exposure time required is. Therefore, the thickness of the PR capable of being formed is limited and the PR is insufficient in thickness for primary etching molding of the microstructure with the high or ultrahigh aspect ratio. When the PR is insufficient in thickness to protect the wafer in the mask region, it is required to take out the to-be-processed wafer to manufacture the mask again.

Therefore, the present disclosure provides a novel mask material silicon carbide (SiC) which is excellent in plasma etching-resistant performance. For etching the microstructure with the same depth-to-width ratio, SiC serving as the mask is relatively thin. Moreover, the SiC mask can be formed by PECVD/PEALD at a relatively low temperature (not higher than 150° C.). The process of forming the SiC in the present disclosure can be performed in dedicated PECVD/PEALD equipment. Given that the process conditions for depositing the SiC mask layer are close to the process conditions for etching the wafer, the etching process for the wafer and the mask deposition process can also be performed in the same plasma processing equipment. By switching to the etching process mode or the mask deposition process mode, the to-be-processed wafer is subjected to in-situ etching or in-situ mask deposition without taking out the to-be-processed wafer from the plasma processing chamber to manufacture the mask again.

“In-situ” described herein refers not to move the to-be-processed wafer, so that the wafer is in the plasma processing chamber all the time in the wafer processing process.

It will be described in detail below in conjunction with drawings.

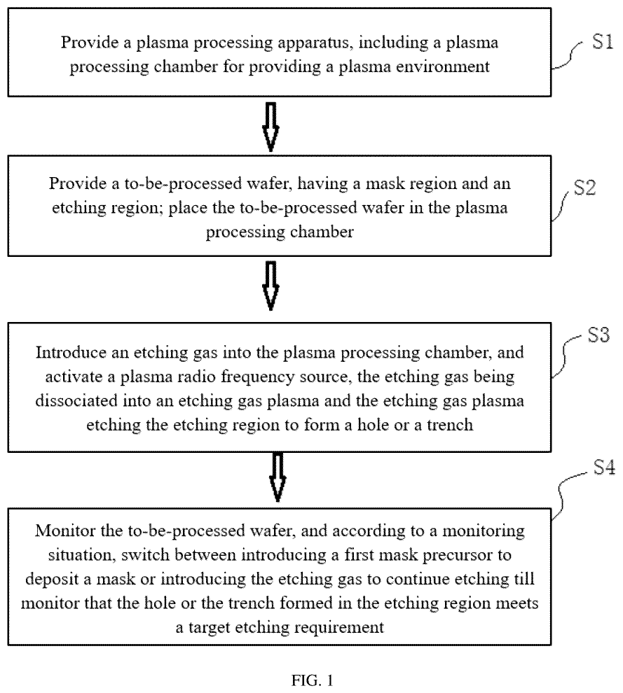

As shown in FIG. 1, a wafer processing method provided by the present disclosure includes:
Step S1: a plasma processing apparatus is provided, including a plasma processing chamber for providing a plasma environment.

The plasma processing apparatus may be used for wafer etching processing and includes an inductively coupled plasma (ICP) reaction apparatus or a capacitively coupled plasma (CCP) reaction apparatus.
Step S2: a to-be-processed wafer is provided, where the to-be-processed wafer has a mask region and an etching region; and the to-be-processed wafer is placed in the plasma processing chamber.

The to-be-processed wafer can be a wafer subjected to lithographic processing, and a mask region thereof has a second mask layer such as the PR. In order to improve the corrosion resistance of the mask, an amorphous C or B layer can also be disposed of between the wafer and the PR. The to-be-processed wafer is made at least one of silicon carbide (SiC), silicon oxide (SiO₂), and silicon (Si).
Step S3: an etching gas is introduced into the plasma processing chamber, and a plasma radio frequency source is activated, the etching gas being dissociated into an etching gas plasma and the etching gas plasma etching the etching region to form a hole or a trench.

The etching gas is an etching gas for conventional wafer processing, such as a mixed gas of N₂/O₂/CO. In the process of etching the to-be-processed wafer, the second mask layer is also gradually etched and thinned.
Step S4: the to-be-processed wafer is monitored, and according to a monitoring situation, it is switched between introducing a first mask precursor to deposit a mask or introducing the etching gas to continue etching till it is monitored that the hole or the trench formed in the etching region meets a target etching requirement.

The first mask precursor includes substituted methylsilane, where an atomic ratio of silicon to carbon is 1:1; the first mask precursor is dissociated into a first mask precursor plasma in the plasma processing chamber, and the first mask precursor plasma deposits a first mask layer in the mask region.

The substituted methylsilane means that in the methylsilane, H atoms on Si—H bonds and/or C—H bonds are partially or totally substituted with halogen, and the halogen can be Cl and/or F. For example, the substituted methylsilane is CH₃SiH₃→CH₃SiCl₃, where Si—H bonds are totally substituted with Cl. In some embodiments, the substituted methylsilane can be at least one of CH₃SiCl₃, CH₂ClSiHCl₂, CHCl₂SiH₂Cl, CH₃SiF₃, CH₂FSiHCl₂, and CHF₂SiH₂F. In the substituted methylsilane, the atomic ratio of Si to C is 1:1. A single substituted methylsilane compound serves as the first mask precursor. Under an action of the plasma radio frequency resource, Si plasmas and C plasmas with Si:C=1:1 are easily dissociated. Furthermore, these Si plasmas and C plasmas form the silicon carbide (SiC) film in situ in the mask region of the to-be-processed wafer without technical problems of a severe requirement on flow and proportion control of various gases by dissimilar gases, so that it can be ensured that the ratio of the Si plasmas to the C plasmas is 1:1, the thickness of the formed first mask layer is controllable, and the process conditions for depositing the mask are low. In the embodiment, the substituted methylsilane is CH₃SiCl₃, a reaction mechanism of which is shown in the following formula (II):

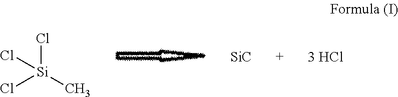

The substituted methylsilane compound selected in the present disclosure is a gas or a liquid that is easy to vaporize, and is introduced to the plasma processing chamber as the first mask precursor. A gas flow rate of the first mask precursor can be 1 sccm-1000 sccm, and a thickness of the formed first mask layer is 1 A−n×10² nm, n=1-10. In a case where thickness of the first mask layer required to be formed is great, the gas flow rate of the first mask precursor is high, too. In a case where the thickness of the first mask layer required to be formed is less, the gas flow rate of the first mask precursor is low, too. According to actual usage requirements, the flow rate, the flow, the introduction time, and the temperature of the gas CH₃SiCl₃ can be controlled to form SiC films with different thicknesses, densities, and uniformities.

In order to control the gas flow rate of the first mask precursor and the density of the SiC film, a carrier gas can also be introduced, and the carrier gas can be helium (He).

In some embodiments, the first mask precursor further includes an oxygen-containing gas which can be at least one of oxygen, ozone or hydrogen peroxide. The formed first mask layer can be a SiOC film or a mixed film of SiC and SiOC.

During real-time monitoring of the to-be-processed wafer in the mask region, in a case that it is monitored that the thickness of the second mask layer (for example, the PR mask) is less than a first preset thickness value (i.e., a basic pattern of the chip is etched), the introduction of the etching gas is stopped and converted to the introduction of O₂ for stripping, so as to remove residual photoresist in a lossless manner. Then it is switched to a refined Bosch process of deposition etching: the first stage is a mask deposition process mode, i.e., the first mask precursor is introduced and dissociated into the first mask precursor plasma under the plasma radio frequency action, and the first mask precursor plasma deposits the first mask layer in the mask region; and in a case that it is monitored that the thickness of the first mask layer reaches a second preset thickness value, introduction of the first mask precursor is stopped and switched to an etching mode in the second stage for continuous etching. The more refined the thickness/shape of the first mask layer is controlled, under its protection, the more refined the critical dimension of the etching of the holes or the trenches in the etching region is controlled. Thus, multiple depositions and etching are performed alternately in situ, so that a microstructure with a great aspect ratio can be made. Through real-time monitoring, it can be ensured that after exposure etching of the basic pattern of the chip, it is immediately switched to the refined etching stage where etching and mask coating are alternate, and precise control of the refined Bosch process is ensured. In some embodiments, the thickness of the first mask layer deposited for the first time is great enough, so that the hole or the trench is etched at one time under the protection of the first mask layer to meet the target etching requirement. That is, the first mask layer is just deposited in situ one time: switched from the initial etching mode to the mask deposition mode and then switched to the etching mode, the hole or the trench can be directly etched to reach the target requirement. In some embodiments, in order to strictly control the morphology of the hole or the trench, the thickness of the first mask layer is less. For example, 1-2 atomic-level first mask layers can be deposited every time. The etching mode and the mask deposition mode are switched many times till it is monitored that the hole or the trench in the etching region meets the target etching requirement, without taking out the wafer from the plasma processing chamber in the wafer processing process to manufacture the mask. The first preset thickness value is the thickness of the mask which at least can basically protect the wafer in the mask region, and can be calculated according to the material of the wafer. The second preset thickness value is the optimum thickness value of the mask calculated according to the requirement of the hole or the trench in the etching process. The first preset thickness value and the second preset thickness value can be preset according to different dimensions of wafers or microstructures of wafers made of different materials.

Since the thickness range of the SiC mask formed by the method provided by the present disclosure is large, from several angstroms to hundreds of nanometers, and SiC is better in corrosion resistance, the wafer processing method provided by the present disclosure is suitable for etching large-sized through-silicon vias (TSV) and forming microstructures with high or ultrahigh aspect ratio. In the embodiment, the microstructure refers to a hole or a trench, and the aspect ratio of the hole or the trench is 5:1-500:1. In some embodiments, the aspect ratio of the hole or the trench is 40:1-200:1. In case that the wafer processing method provided by the present disclosure is used for etching large-sized silicon holes, the silicon holes etched can meet the target requirement by depositing the first mask layer once. Of course, in order to strictly control the morphology of the hole, multiple depositions can also be performed. In a case that the wafer processing method provided by the present disclosure is used for etching the microstructure, the first mask layer can be formed by multiple depositions till the microstructure reaches the target etching requirement.

In some embodiments, in a case that it is monitored that the thickness of the second mask layer is less than the first preset thickness value, the introduction of the etching gas can also be stopped. The oxygen-containing plasma is introduced first to completely remove the residual second mask layer, and then the first mask layer is deposited in the mask region till it is monitored that the thickness of the first mask layer reaches the second preset thickness value.

In order to reduce the process temperature at which the SiC mask is formed, the method for depositing the first mask layer provided by the present disclosure is at least one of PECVD or PEALD. The process temperature of the SiC mask is reduced by means of the plasma environment, so that the SiC mask can be formed at 50° C.-300° C. In some embodiments, the process temperature is 60° C.-200° C.

Since the process conditions such as the temperature ranges and plasma environments in the mask deposition process and the etching process are close, the present disclosure further designs integrated etching-deposition equipment capable of being compatible with the mask deposition process and the etching process for water processing. In-situ etching and mask re-manufacturing are implemented in the same plasma processing chamber without taking out the wafer from the plasma processing chamber in the wafer processing process. It will be described below in conjunction with drawings.

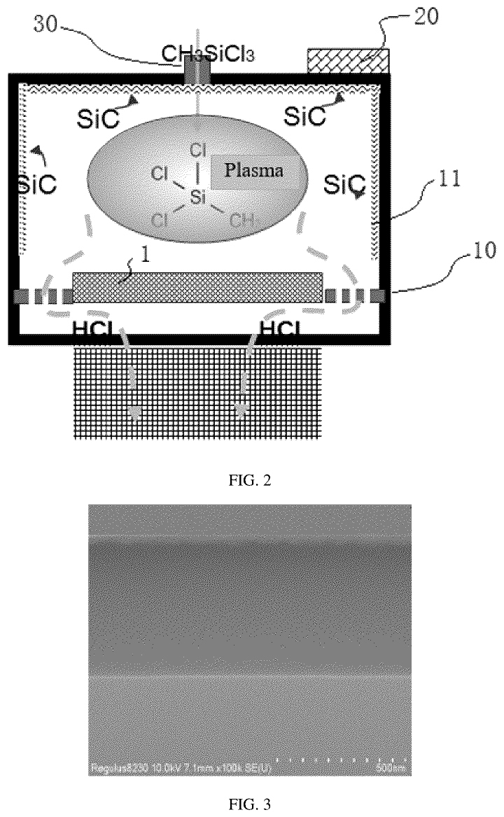

As shown in FIG. 2, integrated etching-deposition equipment for a wafer processing method provided by the present disclosure includes a plasma processing apparatus 10 for wafer etching processing, an online monitoring system 20, and a gas inlet system 30.

The plasma processing apparatus 10 includes an inductively coupled plasma (ICP) reaction apparatus or a capacitively coupled plasma (CCP) reaction apparatus, with a plasma processing chamber 11.

The online monitoring system 20 is in electric connection or signal connection to the plasma processing apparatus 10 for monitoring states of the mask region and the etching region of the to-be-processed wafer 1 in the plasma processing chamber 11 in real time in a water processing process, so as to switch to the etching mode or the mask deposition mode according to a monitoring situation.

In some embodiments, the online monitoring system includes an energy dispersive X-ray spectrometer (EDX) and an automatic data collecting and processing system based on full spectrum for detecting and controlling the thicknesses of the first mask layer and the second mask layer in the mask region in real time.

In some embodiments, the online monitoring system further includes an OES monitoring system for online monitoring an etching state of the etching region, so as to determine whether the target etching requirement is met.

The gas inlet system 30 includes an etching gas inlet pipeline and a first mask precursor gas inlet pipeline, connected with the plasma processing chamber 11 respectively for introducing the etching gas or the first mask precursor into the plasma processing chamber. The etching gas inlet pipeline and the first mask precursor gas inlet pipeline both can be connected with the plasma processing chamber 11 through a same gas inlet or can be connected with the plasma processing chamber 11 through different gas inlets.

In order to precisely control the thickness of the first mask layer, the first mask precursor gas inlet pipeline is further provided with a millisecond-level mass flow controller (not shown in the drawings) for metering a flow of the first mask precursor.

The integrated etching-deposition equipment provided by the present disclosure can be completely manufactured from the beginning or can be obtained by retrofitting an existing plasma processing apparatus. For example, the first mask precursor gas inlet pipeline, the monitoring system for monitoring the mask region of the to-be-processed wafer, the millisecond-level mass flow controller and the like are additionally disposed on an existing ICP or CCP.

### Embodiment 1

The present disclosure provides a wafer processing method, including: A to-be-processed wafer 1 is taken, where, subjected to lithographic processing, the wafer has a mask region and an etching region, and the etching region is covered with a photoresist PR. The to-be-processed wafer 1 is placed on a pedestal of a plasm processing chamber 11 of integrated etching-deposition equipment shown in FIG. 2. Power parameters are as follows: output power of a radio frequency power source is 1500 W, and output power of a radio frequency bias power source is 500 W.

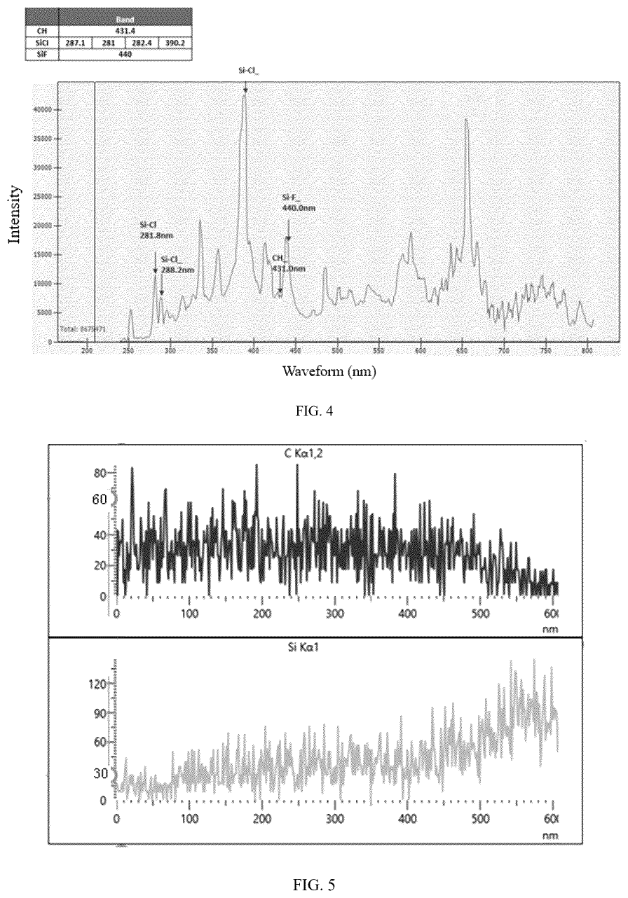

A plasma radio frequency source is activated and the plasm processing chamber 11 is vacuumized to 50 mT. A mixed gas of N₂/O₂/CO is introduced into the plasma processing chamber 11 as an etching gas, and the etching gas is dissociated into an etching gas plasma and etches the etching region to form a hole or a trench. The etching region and the mask region of the to-be-processed wafer are monitored to switch to an etching mode or a mask deposition mode according to a situation. When it is monitored that the thickness of the photoresist PR is lower than a first preset thickness value, it is switched to the mask deposition model: a first mask precursor CH₃SiCl₃ is introduced, with a flow rate of 100 sccm, a carrier gas thereof is He, with a flow rate of 200 sccm, and the temperature of the plasma processing chamber 11 is 60° C. CH₃SiCl₃ is dissociated into carbon ions and silicon ions at an atomic ratio of 1:1 under an action of the plasma radio frequency source, and the carbon ions and the silicon ions form a SiC film in situ in the mask region of the wafer as a first mask layer, as shown in an SEM image in FIG. 3. A spectrogram obtained by online monitoring the plasma processing chamber 11 by the online monitoring system is shown in FIG. 4. A C—H peak (431.4 nm), Si—Cl peaks (287.1 nm, 281 nm, 282.4 nm, and 390.2 nm), and a Si—F peak (440 nm) verify dissociation of CH₃SiCl₃, thereby forming the SiC film. After the mask is deposited for 20 s, the thickness monitored of the SiC film reaches a second preset thickness value. An electro diffraction pattern of the SiC film is shown in FIG. 5. With deep scanning of the SiC film from top to bottom, the content of the element C is significantly decreased from being stable, the content of the element Si is significantly increased from being stable, and the turning point at which the content of the element C is significantly decreased and the content of the element Si is significantly increased is a silicon wafer with the mask region being protected, so that the thickness of the SiC is 500 nm.

Then, it is switched to the etching mode: the introduction of CH₃SiCl₃ is stopped and the introduction of the etching gas N₂/O₂/CO is started to continuously etch the etching region. In case that it is monitored that the thickness of the SiC film is less than the first preset thickness value and the film is insufficient to protect the wafer, etching is stopped, and it is switched again to the mask deposition mode: CH₃SiCl₃ is introduced to deposit a mask; and in a case that it is monitored that the thickness of the SiC film deposited again reaches the second preset thickness value, deposition of the mask is stopped, it is switched again to the etching mode, and the etching gas N₂/O₂/CO is introduced for continuous etching till it is monitored that the hole or the trench formed in the etching region reaches a target etching requirement.

In the present disclosure, the first mask layer is used as a mask for continuous etching. A single deposition may suffice to support the subsequent etching process or two or more depositions may be needed support the subsequent etching process. In some embodiments, in a case that the aspect ratio of the hole or trench required to be formed is less, for example, 5:1, by using the SiC film provided in the present disclosure as the mask; by depositing the SiC film once as the first mask layer, the etching region can be etched to achieve holes or trenches meeting the target etching specifications.

### Embodiment 2

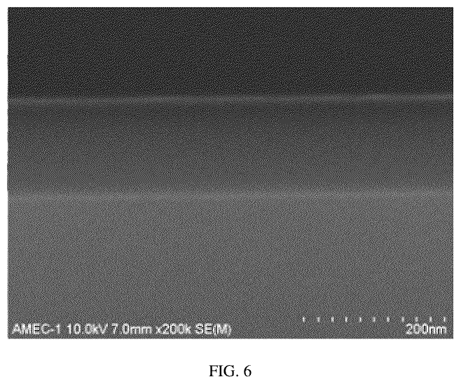

The method is the same as that in the Embodiment 1 is used, just with a different first mask precursor. In the embodiment, the first mask precursor is a mixed gas of CH₃SiCl and O₂: the flow rate of CH₃SiCl₃ is 100 sccm, and a carrier gas thereof is H₂, with a flow rate of 200 sccm; and the flow rate of O₂ is 200 sccm. The deposited first mask layer is a SiOC film, as shown in FIG. 6.

To sum up, the method for forming the mask provided by the present disclosure is PECVD/PEALD. The process temperature at which the SiC film is deposited is not higher than 300° C., so the conditions are mild. The method can be performed in the processing chamber of the wafer etching process. In the wafer processing process, the mask can be in-situ formed without taking out the to-be-processed wafer from the plasma processing chamber, and the hole or the trench of the processed wafer is good in uniformity (CDU is less than 1%). Moreover, the SiC film formed in the present disclosure is better in corrosion resistance and suitable for forming a microstructure with a high or ultrahigh aspect ratio in wafer processing.

While the present disclosure has been described in detail through the above preferred embodiments, it should be understood that the foregoing description shall not be construed as limiting the present disclosure. Various modifications and alternatives to the present disclosure will be readily apparent to those skilled in the art having read the foregoing description. Accordingly, the protection scope of the present disclosure shall be limited by the appended claims.

1. A wafer processing method, comprising:
providing a plasma processing apparatus, comprising a plasma processing chamber for providing a plasma environment;
providing a to-be-processed wafer, having a mask region and an etching region; placing the to-be-processed wafer in the plasma processing chamber;
introducing an etching gas into the plasma processing chamber, and activating a plasma radio frequency source, the etching gas being dissociated into an etching gas plasma and the etching gas plasma etching the etching region to form a hole or a trench; and
monitoring the to-be-processed wafer, and according to a monitoring situation, switching between introducing a first mask precursor to deposit a mask or introducing the etching gas to continue etching till monitoring that the hole or the trench formed in the etching region meets a target etching requirement; and the first mask precursor comprises substituted methylsilane, wherein an atomic ratio of silicon to carbon is 1:1; the first mask precursor is dissociated into a first mask precursor plasma in the plasma processing chamber, and the first mask precursor plasma deposits a first mask layer in the mask region.

2. The wafer processing method according to claim 1, wherein a method for depositing the first mask layer is at least one of PECVD or PEALD.

3. The wafer processing method according to claim 2, wherein a process temperature in the plasma processing chamber is 50° C.-300° C.

4. The wafer processing method according to claim 1, wherein in the substituted methylsilane, H atoms are partially or totally substituted with F and/or Cl.

5. The wafer processing method according to claim 4, wherein the substituted methylsilane is at least one of CH₃SiCl₃, CH₂ClSiHCl₂, CHCl₂SiH₂Cl, CH₃SiF₃, CH₂FSiHCl₂, and CHF₂SiH₂F.

6. The wafer processing method according to claim 1, wherein the first mask layer comprises a SiC film.

7. The wafer processing method according to claim 1, wherein the first mask precursor further comprises an oxygen-containing gas.

8. The wafer processing method according to claim 7, wherein the oxygen-containing gas comprises at least one of oxygen, ozone or hydrogen peroxide.

9. The wafer processing method according to claim 8, wherein the first mask layer comprises a SiC film and/or a SiOC film.

10. The wafer processing method according to claim 1, wherein a monitoring mode for monitoring the to-be-processed wafer is real-time monitoring.

11. The wafer processing method according to claim 1, wherein a thickness of the first mask layer is 1 A−n×10² nm, n=1-10.

12. The wafer processing method according to claim 1, wherein the mask region of the to-be-processed wafer further comprises a second mask layer.

13. The wafer processing method according to claim 12, wherein the second mask layer comprises a photoresist.

14. The wafer processing method according to claim 13, wherein the second mask layer further comprises an amorphous C or B layer, located under the photoresist.

15. The wafer processing method according to claim 1, wherein an aspect ratio of the hole or the trench is 5:1-500:1.

16. The wafer processing method according to claim 1, wherein the aspect ratio of the hole or the trench is 40:1-200:1.

17. Integrated etching-deposition equipment for the wafer processing method according to claim 1, comprising:
a plasma processing apparatus for wafer etching processing, provided with a plasma processing chamber;
an online monitoring system, connected to the plasma processing apparatus for monitoring states of a mask region and an etching region of a to-be-processed wafer in the plasma processing chamber in real time in a water processing process; and
a gas inlet system, comprising an etching gas inlet pipeline and a first mask precursor gas inlet pipeline, connected with the plasma processing chamber respectively for introducing an etching gas or a first mask precursor into the plasma processing chamber.

18. The integrated etching-deposition equipment according to claim 17, wherein the online monitoring system comprises an energy dispersive X-ray spectrometer (EDX) for monitoring the thickness of a first mask layer or a second mask layer in the mask region.

19. The integrated etching-deposition equipment according to claim 17, wherein the online monitoring system comprises an OES monitoring system for online monitoring an etching state of the etching region.

20. The integrated etching-deposition equipment according to claim 17, wherein the first mask precursor gas inlet pipeline is further provided with a millisecond-level mass flow controller for metering a flow of the first mask precursor.

21. The integrated etching-deposition equipment according to claim 17, wherein the plasma processing apparatus comprises an inductively coupled plasma (ICP) reaction apparatus or a capacitively coupled plasma (CCP) reaction apparatus.
